(19) United States
(12) Patent Application Publication
(10) Pub. No.: US 2025/0130881 A1
(43) Pub. Date: Apr. 24, 2025

(54) METHOD FOR STORING MEMORY FAULT DATA, APPARATUS AND COMPUTER PROGRAM FOR PERFORMING THE METHOD

(71) Applicant: UIF (University Industry Foundation), Yonsei University, Seoul (KR)

(72) Inventors: Sung Ho KANG, Seoul (KR); Ha Young LEE, Seoul (KR)

(21) Appl. No.: 18/490,671

(22) Filed: Oct. 19, 2023

(30) Foreign Application Priority Data
Sep. 13, 2022 (KR) 10-2022-0114996

(51) Int. Cl. G06F 11/07

(52) U.S. Cl. CPC G06F 11/0787

(57) ABSTRACT

The present disclosure discloses a method for storing memory fault data. The method of the present disclosure includes selectively storing some of the memory fault data in the fault buffer on the basis of an address of a first line selected from a row or column line of the memory fault data detected from the plurality of fault cells of the memory under test in which the fault occurs; storing an address of a second line and a number of faults in a fault filter on the basis of an address of the remaining second line; and storing some of memory fault data in a fault storage of the memory using information stored in a fault buffer and a fault filter. According to the present disclosure, a hardware overhead of a structure for storing memory fault data is reduced and a time to read the memory fault data is shortened.

### BACKGROUND

### Field

The present disclosure relates to a memory fault data storing method, an apparatus and a computer program for performing the method, and more particularly, to a method, an apparatus, and a computer program for storing memory fault data according to a memory test.

The present invention is a result of research project about “Ultra-high speed memory system (CK 8 GHz DQ 16 Gbps) equipment structure” and a managing department for this research project is the Korea Institute of industrial technology evaluation and management, and the name of the research project is “Industrial technology innovation project”. The project identification number is 1415181114 and the project number is 20019363.

### Description of the Related Art

FIG. 1 is a view for explaining an example of a fault bitmap based memory fault data storing method of the related art.

Referring to FIG. 1, since the introduction of the memory testing and repairing for a memory yield, a fault bitmap has been adopted as a memory fault data storage structure to be widely used to store the memory fault data. This is because as the memory test progresses, the same memory fault is not detected within one memory test pattern, but when the entire memory test pattern is sequentially applied to the memory, the same memory fault is repeatedly detected.

When the fault bitmap is not used, in order to prevent the same memory fault from being stored in a memory fault data storage structure and maintain an available space for another fault, a newly detected fault needs to be compared with all the previously detected faults.

In contrast, in the case of the fault bitmap, only 1 needs to be written in a corresponding position without comparison so that the use of the fault bitmap has become common.

However, in order to classify the memory fault data from the fault bitmap, all data needs to be read from the fault bitmap. However, a size of the fault bitmap is equal to the memory capacity so that in the present time when the memory capacity has exponentially grown, it takes a lot of time to read all the data of the fault bitmap.

### SUMMARY

An object to be achieved by the present disclosure is to provide a memory fault data storing method which reduces a hardware overhead of a structure and an apparatus for storing memory fault data, an apparatus and a computer program for performing the method.

Other and further objects of the present disclosure which are not specifically described can be further considered within the scope easily deduced from the following detailed description and the effect.

In order to achieve an object by the present disclosure, according to an aspect of the present disclosure, a method for storing memory fault data is performed in a memory fault data storing apparatus, including a processor and a memory which stores instructions to execute the method for storing memory fault data performed by the processor and obtained by a fault test for a memory under test to be tested. The method includes: allowing a processor to selectively store some of the memory fault data in the fault buffer of the memory on the basis of an address of a first line selected from a row line or a column line of the memory fault data detected from the plurality of fault cells of the memory under test in which the fault occurs; storing an address of the second line and a number of faults in a fault filter of the memory on the basis of an address of a second line which is another one of a row line or a column line of the memory fault data; and storing some of the selectively stored memory fault data in a fault storage of the memory by considering the address of the second line and the number of faults stored in the fault filter.

Here, the detected memory fault data is sequentially detected while performing a fault test for the memory under test and the first line is a column line and the second line is a column line. The row line of the fault buffer corresponds to the row line of the memory fault data and the column line of the fault buffer includes a counter indicating a number of faults occurring for every row line, and a number of column lines of the fault buffer depends on a number of column line spare resources of the fault buffer and the number of column line spare resources is smaller than a number of column lines of the memory fault data.

Memory fault data which is selectively stored in the fault buffer includes a row line address and a column line address corresponding to a position of a fault cell in which a fault occurs. The processor selectively stores some of the detected memory fault data in the fault buffer on the basis of the row line address.

When the processor selectively stores some of the detected memory fault data in the fault buffer, the processor stores memory fault data detected for some cells selected from cells in which the fault occurs, by considering information stored in the counter and a first reference value which is determined in advance according to the number of column lines of the fault data.

When the processor selectively stores some of the detected memory fault data in the fault buffer, the processor sequentially stores the column line address for the fault occurring in each row line in the fault buffer, and when the number of faults generated in a N-th row line is larger than a number of column direction spare resources, the processor determines the N-th row line as a target of the failure repair and does not store the column line address information in the N-th row line.

In the present disclosure, storing of an address of a second line and a number of faults in a fault filter of the memory includes storing an address of a column line and a number of faults according to the column line in the fault filter of the memory on the basis of the address of the column line, by the processor.

In the present disclosure, the storing of an address of a column line and a number of faults in a fault filter of the memory includes updating a number of faults with regard to the stored column line address while storing a column line address for fault cells which are sequentially stored in the fault buffer for every column line, in the fault buffer.

In the present disclosure, the processor stores memory fault data for some cells selected from fault cells corresponding to the column line in the fault storage by considering a number of updated faults with regard to an address of a column line and a predetermined second reference value. The processor stores row line address information and column line address information for a fault cell stored in the fault buffer in the fault storage and when the number of updated faults stored in the fault buffer exceeds the predetermined second reference value, the M-th column line is determined to be repaired and for the M column line, memory fault data for the fault cell is not stored in the fault storage.

In the present disclosure, the processor sequentially stores memory fault data including row line address information and column line address information for a fault cell in a column line of the fault buffer corresponding to the row line, for every row line and when a number of faults occurring in a N-th row line is larger than a number of column direction spare resources, the processor temporarily stores column line address information for a fault cell related to the N-th row line in an additionally row line. In this case, the processor selectively stores memory fault data for a fault cell which is temporarily stored in the additional row line in the fault storage, by considering a number of faults for the column line stored in the fault buffer.

In order to achieve another object of the present disclosure, a memory fault data storing apparatus includes a processor and a memory which stores instructions which executes the method for storing memory fault data performed by the processor and obtained by a fault test for a memory under test to be tested.

A memory fault data storing method performed by the processor includes allowing a processor to selectively store some of the memory fault data in the fault buffer of the memory on the basis of an address of a first line selected from a row line or a column line of the memory fault data detected from the plurality of fault cells of the memory under test in which the fault occurs; storing an address of the second line and a number of faults in a fault filter of the memory on the basis of an address of a second line which is another one of a row line or a column line of the memory fault data; and storing some of the selectively stored memory fault data in a fault storage of the memory by considering the address of the second line and the number of faults stored in the fault filter.

In order to achieve the above-described technical object, according to an aspect of the present disclosure, a memory fault data storing method includes acquiring first memory fault data for a memory, acquiring second memory fault data by acquiring only fault data required to be stored from the first memory fault data on the basis of a row direction of the memory, acquiring third memory fault data by acquiring only fault data required to be stored from the second memory fault data on the basis of a column direction of the memory, and storing the third memory fault data as final memory fault data required to repair the memory.

Here, the acquiring of first memory fault data is configured by acquiring the first memory fault data including first fault data detected while performing the test of the memory.

Here, the acquiring of second memory fault data is configured by acquiring the second memory fault data from the first memory fault data using a fault buffer having the same number of rows as the number of rows of the memory and a number of columns set based on the number of column direction spare resources.

Here, the acquiring of the second memory fault data is configured by storing a first column address of the first fault data in an empty column of a row of the fault buffer corresponding to a first row address of the first fault data when the first fault data configured by a first row address and a first column address according to the first memory fault data is input to the fault buffer, increasing a value of a count column corresponding to a row of the fault buffer by 1, setting a row address corresponding to a row of the fault buffer as a row direction repair required row when a value of a count column corresponding to a row of the fault buffer is larger than a number of column direction spare resources, and not storing the first fault data in the fault data because when there is no empty column in the row of the fault buffer corresponding to a first row address of the first fault data, a row address corresponding to a row of the fault buffer is a repair requested row in the row direction.

Here, the acquiring of second memory fault data is configured by acquiring the second memory fault data including the first fault data as second fault data when the first fault data is stored in the fault buffer.

Here, the acquiring of third memory fault data is configured by acquiring the third memory fault data from the second memory fault data using a fault filter having the same number of rows as the number of rows of the memory and two columns in which a column address and a count value are stored.

Here, in the acquiring of third memory fault data, when the second fault data configured by a second row address and a second column address, according to the second memory fault data, is input, if the second column address of the second fault data is already stored in the column address column of the fault filter and a value of a count column corresponding to the stored column address column is equal to or smaller than the number of column direction spare resources, the processor increases a value of the count column corresponding to the stored column address column by 1. When a value of the count column corresponding to the stored column address column is larger than the number of row direction spare resources, the processor sets the column address corresponding to the second column address of the second fault data as a column direction repair requested row. The column address corresponding to the second column address of the second fault data is the column direction repair required row so that the processor may not store the second fault data in the fault filter. When the second column address of the second fault data is not stored in the column address column of the fault filter, the processor stores the second column address of the second fault data in an empty row of the column address column and increases a value of the count column corresponding to the column address column by 1.

Here, the acquiring of third memory fault data is configured by acquiring the third memory fault data including the second fault data as third fault data when the second fault data is stored in the fault filter.

Here, the storing of final memory fault data is configured by storing the third fault data configured by a third row address and a third column address, according to the third memory fault data, as final fault data in the fault storage to store final memory fault data required to repair the memory.

In order to achieve the above-described technical object, according to an aspect of the present disclosure, a computer program is stored in a computer readable storage medium to allow a computer to execute any one of the above memory fault data storing methods.

In order to achieve the above-described technical object, according to an aspect of the present disclosure, a memory fault data storing apparatus includes a memory which stores one or more programs to store memory fault data; and one or more processors which perform an operation for storing memory fault data according to one or more programs stored in the memory. The processor acquires first memory fault data for the memory, acquires second memory fault data by acquiring only fault data required to be stored from the first memory fault data on the basis of a row direction of the memory, acquires third memory fault data by acquiring only fault data required to be stored from the second memory fault data on the basis of a column direction of the memory, and stores the third memory fault data as final memory fault data required to repair the memory.

Here, the processor acquires first memory fault data including first fault data which is detected while performing the test of the memory.

Here, the processor acquires the second memory fault data from the first memory fault data using a fault buffer having the same number of rows as the number of rows of the memory and a number of columns set based on the number of column direction spare resources.

A memory fault data storing method, an apparatus and a computer program for performing the method according to the exemplary embodiment of the present disclosure reduce a hardware overhead of a structure and an apparatus for storing memory fault data, and shorten the time to read the memory fault data to significantly reduce the entire memory test and repair cost.

The effects of the present disclosure are not limited to the technical effects mentioned above, and other effects which are not mentioned can be clearly understood by those skilled in the art from the following description

### BRIEF DESCRIPTION OF THE DRAWINGS

FIG. 1 is a view for explaining an example of a fault bitmap based memory fault data storing method of the related art;

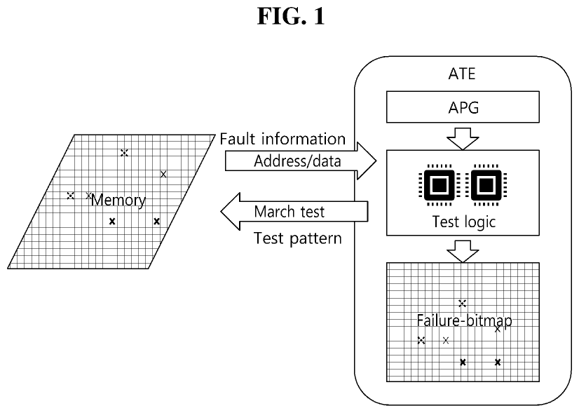

FIG. 2 is a block diagram for explaining a memory fault data storing apparatus according to an exemplary embodiment of the present disclosure;

FIG. 3 is a flowchart for explaining a memory fault data storing method according to an exemplary embodiment of the present disclosure;

FIG. 4 is a view for explaining an example of a memory fault data storing method according to an exemplary embodiment of the present disclosure; and

FIG. 5 is a view illustrating an example of unrequired faults according to an exemplary embodiment of the present disclosure.

### DETAILED DESCRIPTION OF THE EMBODIMENT

Hereinafter, embodiments of the present invention will be described in detail with reference to the accompanying drawings. Advantages and characteristics of the present invention and a method of achieving the advantages and characteristics will be clear by referring to exemplary embodiments described below in detail together with the accompanying drawings. However, the present disclosure is not limited to exemplary embodiments disclosed herein but will be implemented in various different forms. The exemplary embodiments are provided by way of example only so that a person of ordinary skilled in the art can fully understand the disclosures of the present invention and the scope of the present invention. Therefore, the present invention will be defined only by the scope of the appended claims. Like reference numerals indicate like elements throughout the specification.

Unless otherwise defined, all terms (including technical and scientific terms) used in the present specification may be used as the meaning which may be commonly understood by the person with ordinary skill in the art, to which the present disclosure belongs. It will be further understood that terms defined in commonly used dictionaries should not be interpreted in an idealized or excessive sense unless expressly and specifically defined.

In the specification, the terms “first” and “second” are used to distinguish one component from the other component so that the scope should not be limited by these terms. For example, a first component may also be referred to as a second component and likewise, the second component may also be referred to as the first component.

In the present specification, in each step, numerical symbols (for example, a, b, and c) are used for the convenience of description, but do not explain the order of the steps so that unless the context apparently indicates a specific order, the order may be different from the order described in the specification. That is, the steps may be performed in the order as described or simultaneously, or an opposite order.

In this specification, the terms “have”, “may have”, “include”, or “may include” represent the presence of the characteristic (for example, a numerical value, a function, an operation, or a component such as a part”), but do not exclude the presence of additional characteristic.

Hereinafter, an exemplary embodiment of a memory fault storing method, an apparatus and a computer program for performing the same according to the present disclosure will be described in detail with reference to the accompanying drawings.

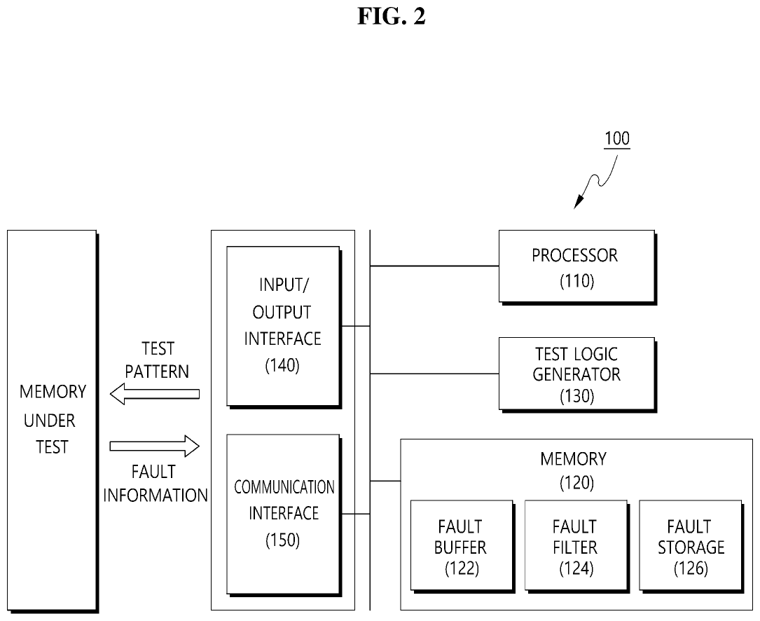

First, a memory fault data storing apparatus according to an exemplary embodiment of the present invention will be described with reference to FIG. 2.

FIG. 2 is a block diagram for explaining a memory fault data storing apparatus according to an exemplary embodiment of the present disclosure. Referring to FIG. 2, a memory fault data storing apparatus 100 according to an exemplary embodiment of the present disclosure may reduce a hardware overhead of a structure and an apparatus for storing memory fault data and shorten a time to read the memory fault data. Accordingly, according to the present disclosure, the entire memory test repair costs may be significantly reduced.

The memory fault data storing apparatus 100 illustrated in FIG. 2 includes a processor 110, a memory 120, a test logic generator 130, an input/output interface 140, and a communication interface 150. In FIG. 2, a memory under test is a target of a fault test.

The memory fault data storing apparatus 100 according to the present disclosure may be automated test equipment (ATE) for diagnosing the fault of the memory. The test logic generator 130 generates a test logic for diagnosing a memory under test or a previously designed algorithm pattern. As the test logic generator, for example, an algorithmic pattern generator (APG) is used. The test logic generator 130 generates a signal related to a test logic to transmit the test logic to the memory under test at the outside through the input/output interface 140 or the communication interface 150. The test logic generator 130 may be implemented as hardware or software. A source code for generating a test logic signal may be stored in the memory 120 and the processor 110 may be implemented to perform an operation for generating a test logic signal.

A memory fault data storing apparatus of the related art stores and manages the memory fault data in the form of a fault bitmap. However, the memory fault data storing apparatus of the present exemplary embodiment selectively stores required fault data excluding unrequired fault data from the memory fault data obtained as a memory test result. The processor 110 controls the memory fault data storing apparatus 100 to operate. For example, the processor 110 may execute one or more programs stored in the memory 120 or a computer readable storage medium. One or more programs may include one or more computer executable instructions and the computer executable instruction may be configured to allow the memory fault data storing apparatus 100 to perform the operation for storing memory fault data when it is executed by the processor 110.

The input/output interface 140 is connected to the processor 110 and the test logic generator 130 through a data bus and enables the data transmission with the external device. The input/output interface 140 provides a test pattern signal including a test logic to an external memory (memory under test) to be tested. The test pattern signal may also be transmitted to the memory under test through the communication interface 150.

When the memory under test includes a fault cell, a response of the memory under test for the test pattern signal includes fault information (memory fault data) detected from fault cells. The memory fault data includes position information (row line address information or column line address information) of the fault cell.

The memory 120 (including a computer readable storage medium) is configured to store a computer executable instruction or program code, program data and/or other appropriate format of information to store memory fault data. The memory may be a volatile memory such as a random access memory (RAM), a nonvolatile memory, or an appropriate combination thereof. Further, the memory may be one or more magnetic disc storage devices, optical disc storage devices, flash memory devices, and another type of storage media which are accessed by the memory fault data storing apparatus 100 and stores desired information, or an appropriate combination thereof.

Desirably, the memory 120 of the present embodiment includes a fault buffer 122, a fault filter 124, and a fault storage 126. The fault buffer, the fault filter, and the fault storage refer to areas of the memory in which the data is stored. The fault buffer, the fault filter, and the fault storage may be implemented as a separate memory or may also be implemented such that different storage areas are allocated in one memory.

The processor 110 selectively stores some of the memory fault data detected from the memory under test in the fault buffer 122. The processor 110 selectively stores some of the memory fault data in the fault buffer of the memory on the basis of an address of a first line selected from a row line or a column line of the memory fault data detected from the plurality of fault cells of the memory under test in which the fault occurs. Here, the first line is a row line and the second line is a column line, or vice versa.

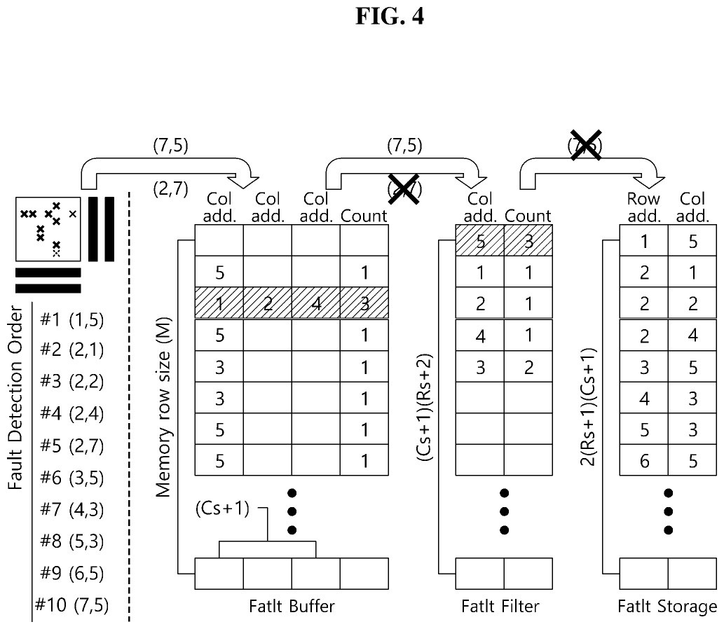

Referring to FIG. 4, “fault detection order” refers to an order of sequentially detecting fault information about the fault cell. The memory fault data is a concept of a set of the fault information. The processor 110 of the embodiment does not store all the acquired memory fault data in the fault storage, but may selectively store the acquired memory fault data.

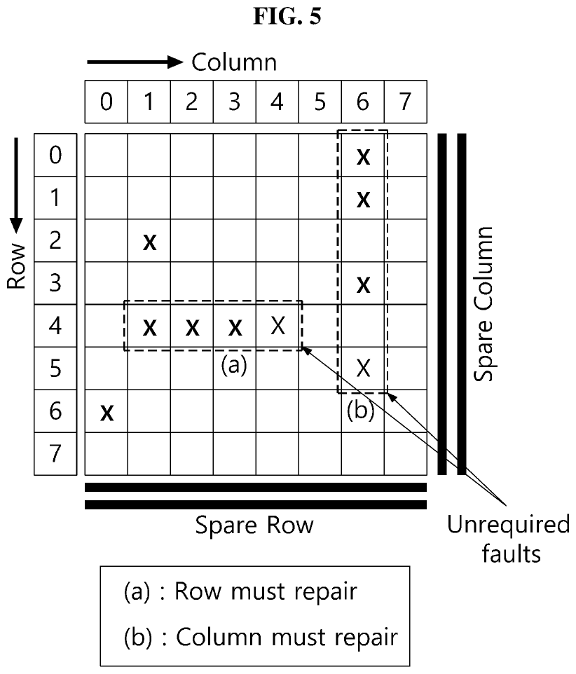

First, the processor 110 selectively stores some of the memory fault data in the fault buffer 122. Referring to FIG. 4, when the row line is the first line and the column line is the second line, the row line of the fault buffer 122 is desirably implemented so as to correspond to a row line of the fault memory data. The number (size) of column lines of the fault buffer depends on a number of column line spare resources (for example, spare columns of FIG. 5). Desirably, the number of column lines of the fault buffer is smaller than the number of column lines of an area of the memory under test having data and is larger than the number of column line spare resources. The column line of the fault buffer includes a column line address area for storing a column line address of the fault cell in which the fault occurs and a counter. The counter stores the address information of the column line as a number of column lines in which the fault occurs in the corresponding row line so that the counter value is increased.

For example, there are four fault cells in a second column, the processor 110 sequentially stores the column line address information of the fault cell in the fault buffer. The value of the counter refers to a number of stored column line address information. In the present embodiment, the processor 110 compares information stored in the counter and a first reference value determined in advance according to a number of column lines of the fault buffer. The processor 110 determines whether to consider the row line as a row line to be repaired according to the comparison result. With regard to the row line determined as a row line to be repaired, even though there are additional fault cells, the processor does not store column line address information for the additional fault cells in the fault buffer. Here, the first reference value is a maximum number of fault cells to be recorded in the fault buffer and in FIG. 4, the first reference value is 3. When the value of the counter is 3, information #5(2,7) is not recorded in the fault buffer. Further, the processor 110 determines the corresponding row line as a row line to be repaired according to the comparison result.

The processor 110 of the embodiment sequentially stores the column line address information for the fault occurring in each row line in the fault buffer and selectively stores some memory fault data in a column line which satisfies a specific condition. For example, when the number of faults generated in a N-th row line is larger than a number of column direction spare resources, an operation of determining the N-th row line as a target of the fault repair and not storing the column line address information in the N-th row line may be performed.

According to a method for storing memory fault data, memory fault data for a fault cell which is temporarily stored in the additional row line is selectively stored in the fault storage by considering the number of faults for the column line stored in the fault buffer.

Next, the processor 110 stores an address of a second line and a number of faults on the basis of the address of the second line which is another one of the row line or the column line of the memory fault data in the fault filter 124.

When the first line is a row line and the second line is a column line, the processor 110 stores address information of the column line and the number of faults occurring in the column line in the fault filter 124 on the basis of the column line address. The processor counts the number of faults for every column line from the memory fault information which is selectively stored in the fault buffer. For example, referring to FIG. 4, the processor does not store information of #5(2,7) which is initially acquired in the fault buffer so that the presence of a fault cell for a seventh column of #5(2,7) is not counted in the fault filter.

The fault filter includes an area in which address information of the column line is stored and a counter. The counter stores information about the number of fault cells on the basis of the column line.

Referring to FIG. 4, in “5,3” which is the first row of the fault filter, “5” indicates column line information of #1(1,5) which is the first fault cell. “3” indicates a “number of fault cells in which fault occurs in the fifth column line”. However, referring to FIG. 4, the number of fault cells of the fifth column line is illustrated as “4”. In the present embodiment, a predetermined second reference value to be described below is a maximum value of a counter value of the fault filter 124. Referring to FIG. 4, the second reference value is “3” and the counter value is increased in accordance with the number of recognized fault cells, but does not exceed “3”. When the counter value corresponds to the second reference value, the processor 110 does not count the number of fault cells occurring in the corresponding column line and determines the corresponding cell line as a column line to be repaired.

In other words, the processor 110 of the present embodiment stores row line address information and the column line address information for the fault cell stored in the fault buffer in the fault storage. However, when the number of updated faults stored in the fault buffer exceeds a predetermined second reference value, the processor 110 determines the M-th column line as a target of the fault repair. With respect to the M column line, the memory fault data for the fault cell is not stored in the fault storage.

Next, the processor 110 stores some of the selectively stored memory fault data in the fault storage 126 of the memory by considering the address of the second line stored in the fault filter 124 and the number of faults. The processor 110 selects and stores some of the memory fault data stored in the fault buffer 122 in the fault storage 126 referring to information stored in the fault filter 124. In the fault filter 124, a column line address and information of a number of faults occurring in the column line address are stored. When the counter value of the fault filter corresponds to the second reference value, the processor 110 deletes memory fault information (referring to FIG. 4, corresponding to #10(7,5)) about the fault cell occurring in the column line and finally stores the memory fault data which is not deleted and stored in the fault buffer in the fault storage 126.

According to another embodiment of the present disclosure, when the number of faults is larger than the number of column direction spare resources, fault information of an additional fault cell is not deleted, but may be temporarily stored in an additional row direction.

The additional row line may be located in an additional fault buffer (not illustrated) separated from the fault buffer or located below the fault buffer, but is not limited thereto. Since a row line which is being currently processed has been already classified as a repair target, information about a fault cell which is not required to be stored is stored in the additional row line. The processor temporarily stores fault cell information (a row line address and a column line address) which is not required to be stored any more or is to be deleted in the additional fault buffer. In this case, the processor generates information and inputs the information to the fault filter by considering not only information stored in the fault buffer, but also information which is temporarily stored in the fault filter.

With regard to the column line address of the fault cell which is temporarily stored in the additional row line, the processor counts the number of fault cells occurring in the column line address, by further considering the fault cell. If the number of fault cells is smaller than the second reference value, the fault information of the additional fault cell which is temporarily stored in the additional row line is deleted. In contrast, when the number of fault cells is equal to or exceeds the second reference value, the fault information of the additional fault cell is not deleted. By doing this, in the step of fault buffer 122, the deletion is performed so that an error of omitting from the column line to be repaired may be reduced.

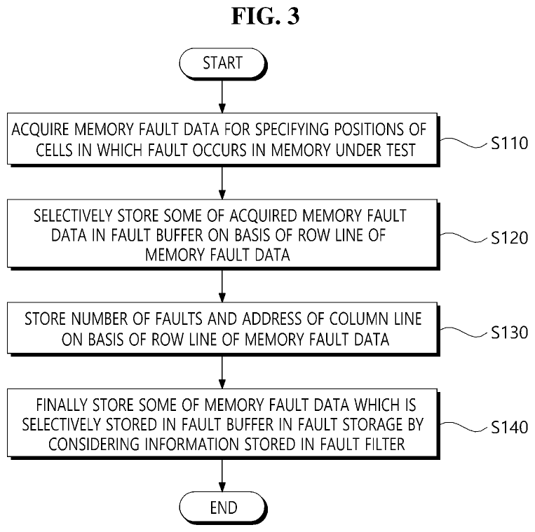

Now, a memory fault data storing method according to an exemplary embodiment of the present disclosure will be described with reference to FIG. 3.

FIG. 3 is a flowchart for explaining a memory fault data storing method according to an exemplary embodiment of the present disclosure. Steps illustrated in FIG. 3 include the following steps which are performed in series in the memory fault data storing apparatus 100. The repeated matters with the description of FIG. 2 will be omitted.

Referring to FIG. 3, the processor 110 of the memory fault data storing apparatus 100 acquires memory fault data for specifying positions of fault cells of the memory under test in which fault occurs (S110). The memory fault data includes cell position information of the memory under test and information stored in each cell as a response obtained by applying a test pattern to the memory under test. A method for determining whether the fault occurs in the memory under test is not specifically limited and the processor 110 may easily acquire information (memory fault data) about the fault cell in which the fault occurs using various known methods as illustrated in an upper left side of FIG. 4.

Next, the processor 110 selects some of acquired memory fault data in the fault buffer on the basis of the row line of the memory fault data (S120). The row line of the fault buffer corresponds to a row line of the memory under test and in the column line, column line information of the fault cell present in the corresponding row line is sequentially stored. The column line includes an area in which the column line information is stored and a count.

Next, the processor 110 stores the number of faults and an address of the column line in the fault filter 124 on the basis of the column line of the memory fault data (S130). Referring to FIG. 4, address information of the column line and the counter value are stored in the column line of the fault filter. The processor sequentially records information of the fault cell stored in the fault buffer, in the fault filter. When the counter value does not exceed the second reference value, for example, as illustrated in FIG. 4, the second reference value is 3, the processor determines a cell whose counter value is 3 as a cell line to be repaired. In the case of the cell which is determined as a cell line to be repaired, the processor does not store information about the fault cell as final memory fault data.

Next, the processor 110 stores some of the memory fault data stored in the fault buffer in the fault storage 126 as final memory fault data using information stored in the fault filter.

According to another exemplary embodiment of the present disclosure, the processor 110 of the memory fault data storing apparatus 100 may acquire first memory fault data for the memory. That is, the processor 110 acquires first memory fault data including first fault data which is detected while performing the test of the memory.

Next, the processor 110 acquires only fault data which is required to be stored from the first memory fault data on the basis of the row direction of the memory to acquire second memory fault data. At this time, the processor 110 acquires the second memory fault data from the first memory fault data using a fault buffer. Here, the fault buffer may have the same number of rows as the number of rows of the memory and a number of columns (column address columns in which the column address is stored and a count column in which the count value is stored) set based on the number of column direction spare resources. That is, when the first fault data configured by a first row address and a first column address, according to the first memory fault data, is stored in the fault buffer, the processor 110 stores the first column address of the first fault data in an empty column of a row of the fault buffer corresponding to the first row address of the first fault data, increases a value of the count column corresponding to a row of the fault buffer by 1. When the value of the count column corresponding to the row of the fault buffer is larger than the number of column direction spare resources, the processor 110 sets a row address corresponding to the row of the fault buffer as a row which is requested to be repaired in the row direction. In contrast, when there is no empty column in the row of the fault buffer corresponding to the first row address of the first fault data, since the row address corresponding to the row of the fault buffer is a row which is required to be repaired in the row direction, the processor 110 may not store the first fault data in the fault buffer.

When the first fault data is stored in the fault buffer, the processor 110 acquires second memory fault data including the first fault data as the second fault data.

Next, the processor 110 acquires only fault data which is required to be stored from the second memory fault data on the basis of the column direction of the memory to acquire third memory fault data. At this time, the processor 110 acquires the third memory fault data from the second memory fault data using a fault filter. Here, the fault filter may have the same number of rows as the number of columns of the memory and two columns (a column address column and a count column) in which the column address and the count value are stored.

That is, when the second fault data configured by a second row address and a second column address, according to the second memory fault data, is input, if the second column address of the second fault data is already stored in the column address column of the fault filter and a value of a count column corresponding to the stored column address column is equal to or smaller than the number of column direction spare resources, the processor 110 increases a value of the count column corresponding to the stored column address column by 1. In the meantime, when a value of the count column corresponding to the stored column address column is larger than the number of row direction spare resources, the processor 110 sets the column address corresponding to the second column address of the second fault data as a column direction repair requested row. The column address corresponding to the second column address of the second fault data is the column direction repair required row so that the processor may not store the second fault data in the fault filter. In contrast, when the second column address of the second fault data is not stored in the column address column of the fault filter, the processor 110 stores the second column address of the second fault data in an empty row of the column address column and increases a value of the count column corresponding to the column address column by 1.

When the second fault data is stored in the fault filter, the processor 110 acquires third memory fault data including the second fault data as the third fault data.

Next, the processor 110 may store the third memory fault data as final memory fault data required to repair the memory.

That is, the processor 110 stores the third fault data configured by a third row address and a third column address, according to the third memory fault data, as final fault data in the fault storage to store final memory fault data required to repair the memory.

Now, an example of a memory fault data storing method according to an exemplary embodiment of the present disclosure will be described with reference to FIGS. 4 and 5.

FIG. 4 is a view for explaining an example of a memory fault data storing method according to an exemplary embodiment of the present disclosure.

Referring to FIG. 4, faults which are detected while performing the memory test are sequentially sent to the fault buffer and column addresses of the detected faults may be stored in a determined row address location.

At this time, if a number of faults occurring in one row, like a row address “2”, is larger than the number of column direction spare resources and a row is confirmed to be repaired in the row direction, the row may no longer store additional fault data.

Accordingly, fault data which needs to be read may be reduced unlike the related art.

Further, at a test cycle at which the fault is not detected, fault data of the fault buffer is transmitted to the fault filter to check column direction faults based on the memory column address in the fault filter to confirm a row which is confirmed to be repaired in the column direction and remove unrequired column direction faults.

Finally, remaining faults excluding faults filtered by the fault filter are stored in the fault storage and memory fault data after the test may be read to repair the memory only in the fault storage.

FIG. 5 is a view illustrating an example of unrequired faults according to an exemplary embodiment of the present disclosure.

“row must repair” means that a number of faults occurring in one memory row is larger than a number of column direction spare resources. In the case of the “row must repair” illustrated in FIG. 5, a number of faults occurring in the memory column is “four”, but the number of column direction repair resources is “two” so that the faults in the row is not repaired even using all the column direction spare resources.

Accordingly, the corresponding column needs to be repaired as a row direction repair resource to be designated as “row must repair”.

Even though red-colored fault data in the “row must repair” is not present during the fault analysis for repair, the corresponding memory row already has three faults, it is determined to correspond to “row must repair”.

Accordingly, in the present disclosure, when three faults representing in “row must repair” are already stored in the fault buffer, the red-colored unrequired fault may not be additionally stored in the fault buffer.

Similarly, in the case of “column must repair”, as considered by the fault filter, the fault filter may not store the fault data such as the red colored unrequired fault in “column must repair”.

The operation according to the embodiment of the present disclosure may be implemented as a program instruction which may be executed by various computers to be recorded in a computer readable storage medium. The computer readable storage medium indicates an arbitrary medium which participates to provide a command to a processor for execution. The computer readable storage medium may include solely a program command, a data file, and a data structure or a combination thereof. For example, the computer readable medium may include a magnetic medium, an optical recording medium, and a memory. The computer program may be distributed on a networked computer system so that the computer readable code may be stored and executed in a distributed manner. Functional programs, codes, and code segments for implementing the present embodiment may be easily inferred by programmers in the art to which this embodiment belongs.

The present embodiments are provided to explain the technical spirit of the present embodiment and the scope of the technical spirit of the present embodiment is not limited by these embodiments. The protection scope of the present embodiments should be interpreted based on the following appended claims and it should be appreciated that all technical spirits included within a range equivalent thereto are included in the protection scope of the present embodiments.

1. A method for storing memory fault data performed in a memory fault data storing apparatus, including a processor and a memory which stores instructions to execute operations for storing memory fault data performed by the processor and obtained by a fault test for a memory under test to be tested, the operations comprising:
allowing the processor to selectively store some of the memory fault data in the fault buffer of the memory on the basis of an address of a first line selected from a row line or a column line of the memory fault data detected from the plurality of fault cells of the memory under test in which the fault occurs;
storing an address of the second line and a number of faults in a fault filter of the memory on the basis of an address of a second line which is another one of a row line or a column line of the memory fault data; and
storing some of the selectively stored memory fault data in a fault storage of the memory by considering the address of the second line and the number of faults stored in the fault filter.

2. The method according to claim 1, wherein the detected memory fault data is sequentially detected while performing a fault test for the memory under test and the first line is a column line and the second line is a column line.

3. The method according to claim 2, wherein a row line of the fault buffer corresponds to a row line of the memory fault data and the row line of the fault buffer includes an address of a cell line in which the fault occurs in the row line and a counter indicating a number of faults occurring in the row line.

4. The method according to claim 2, wherein memory fault data which is selectively stored in the fault buffer includes a row line address and a column line address corresponding to a position of a fault cell in which a fault occurs,
a number of column lines of the fault buffer depends on a number of column line spare resources of the fault buffer and the number of column line spare resources is smaller than a number of column lines of the memory fault data, and
the processor selectively stores some of the detected memory fault data in the fault buffer on the basis of the row line address.

5. The method according to claim 3, wherein when some of the detected memory fault data is selectively stored in the fault buffer, the processor stores memory fault data detected for some cells selected from cells in which the fault occurs, by considering information stored in the counter and a first reference value which is determined in advance according to the number of column lines of the fault data.

6. The method according to claim 2, wherein when the processor selectively stores some of the detected memory fault data in the fault buffer, the processor sequentially stores the column line address for the fault occurring in each row line in the fault buffer, and
when the number of faults generated in a N-th row line of the memory under test is larger than a number of column direction spare resources, the processor determines the N-th row line as a target of the failure repair and does not store the column line address information for the N-th row line.

7. The method according to claim 1, wherein the first line is a row line and the second line is a column line and
when the address of the second line and the number of faults are stored in a fault filter of the memory, the processor stores an address of the column line included in the memory fault data stored in the fault buffer and the number of faults according to the column line in a fault filter of the memory.

8. The method according to claim 1, wherein the first line is a row line and the second line is a column line and
the storing of the address of the column line and the number of faults in a fault filter of the memory on the basis of an address of a column line of the memory fault data includes:
updating a number of faults related to the stored column line address while storing a column line address for each of fault cells which is sequentially stored in the fault buffer in the fault buffer.

9. The method according to claim 8, wherein when the processor stores some of memory fault data stored in the fault buffer in the fault storage, memory fault data for some fault cells selected from fault cells corresponding to the column line is stored in the fault storage by considering a number of updated faults with regard to the address of the column line and a predetermined second reference value.

10. The method according to claim 2, wherein when the processor stores some of memory fault data stored in the fault buffer in the fault storage, row line address information and column line address information for a fault cell stored in the fault buffer are stored in the fault storage and
when the number of updated faults stored in the fault buffer exceeds the predetermined second reference value, the M-th column line is determined to be repaired and for the M column line, memory fault data for the fault cell is not stored in the fault storage.

11. The method according to claim 2, wherein when the processor selectively stores some of the detected memory fault data in the fault buffer, the processor sequentially stores memory fault data including row line address information and column line address information for the fault cell in a row line of the fault buffer corresponding to the row line for every row line,
when a number of faults occurring in a N-th row line is larger than a number of column direction spare resources, the processor temporarily stores column line address information for a fault cell related to the N-th row line in an additional row line and the processor selectively stores memory fault data for a fault cell which is temporarily stored in the additional row line in the fault storage by considering a number of faults for the column line stored in the fault buffer.

12. A computer program stored in a computer readable storage medium to allow a computer to execute the memory fault data storing method according to claim 1.

13. A memory fault data storing apparatus, comprising:
a processor and a memory which stores instructions which is performed by the processor and executes operations for storing memory fault data obtained by a fault test for a memory under test to be tested, wherein the operations executed by the processor include:
allowing the processor to selectively store some of the memory fault data in the fault buffer of the memory on the basis of an address of a first line selected from a row line or a column line of the memory fault data detected from the plurality of fault cells of the memory under test in which the fault occurs;
storing an address of the second line and a number of faults in a fault filter of the memory on the basis of an address of a second line which is another one of a row line or a column line of the memory fault data; and
storing some of the selectively stored memory fault data in a fault storage of the memory by considering the address of the second line and the number of faults stored in the fault filter.

14. The apparatus according to claim 13, wherein the detected memory fault data is sequentially detected while performing a fault test for the memory under test and the first line is a column line and the second line is a column line, and a row line of the fault buffer corresponds to a row line of the memory fault data and the row line of the fault buffer includes an address of a cell line in which the fault occurs in the row line and a counter indicating a number of faults occurring in the row line.

15. The apparatus according to claim 14, wherein memory fault data which is selectively stored in the fault buffer includes a row line address and a column line address corresponding to a position of a fault cell in which a fault occurs,
a number of column lines of the fault buffer depends on a number of column line spare resources of the fault buffer and the number of column line spare resources is smaller than a number of column lines of the memory fault data, and
the processor selectively stores some of the detected memory fault data in the fault buffer on the basis of the row line address.

16. The apparatus according to claim 15, wherein when some of the detected memory fault data is selectively stored in the fault buffer, the processor stores memory fault data detected for some cells selected from cells in which the fault occurs, by considering information stored in the counter and a first reference value which is determined in advance according to the number of column lines of the fault data and
when the address of the second line and the number of faults are stored in a fault filter of the memory, the processor stores an address of the column line included in the memory fault data stored in the fault buffer and the number of faults according to the column line in a fault filter of the memory.

17. The apparatus according to claim 15, wherein when the processor stores some of memory fault data stored in the fault buffer in the fault storage, the processor stores memory fault data for some fault cells selected from fault cells corresponding to the column line in the fault storage by considering a number of updated faults with regard to the address of the column line and a predetermined second reference value.
